(19) United States
(12) Patent Application Publication
(10) Pub. No.: US 2007/0082475 A1
(43) Pub. Date: Apr. 12, 2007

(54) Method for forming bonding pad and semiconductor device having the bonding pad formed thereby

(75) Inventor: Jeong Ho Park, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/546,259

(22) Filed: Oct. 12, 2006

(30) Foreign Application Priority Data
Oct. 12, 2005 (KR) 10-2005-0096035
Oct. 12, 2005 (KR) 10-2005-0096037
Oct. 28, 2005 (KR) 10-2005-0102301
Nov. 15, 2005 (KR) 10-2005-0108950

(51) Int. Cl. H01L 21/44

(52) U.S. Cl. 438/612

(57) ABSTRACT

A first insulating film is formed on a substrate or a lower metal wiring, and a first metal layer is formed on the first insulating film. A second insulating film and a third insulating film are formed on the first insulating film and the first metal layer, and the third insulating film and the second insulating film are selectively slope-etched by using a first photosensitive film mask to form a sloped pad opening portion. A barrier metal layer and a pad metal layer are formed over the substrate, and the pad metal layer and the barrier metal layer are selectively etched by using a second photosensitive film mask to form a bonding pad. A fourth insulating film is formed over the substrate, and the fourth insulating film is selectively etched by using a third photosensitive film mask to expose a part of the bonding pad.

### FIELD OF THE INVENTION

The present invention relates generally to a bonding pad of a semiconductor device and, more particularly, to a bonding pad capable of preventing Cu from being diffused by using a sloped pad opening portion to form a barrier metal film thereon, and a semiconductor device including the bonding pad.

### BACKGROUND OF THE INVENTION

The semiconductor device includes internal circuits therein which have various functions. The internal circuits should be electrically connected to an external system to fully realize their functions. In order to electrically connect the internal circuits of the semiconductor device to the external system as described above, the semiconductor is provided with a plurality of pads.

A conducting wire made of, for instance, gold (Au) is bonded by a bonding wire to the pad described above, so that the internal circuits and the external system may share data. At this time, a metal coating made of, for instance, Al is formed in order to bond to an adhesive region on the semiconductor device. Such an adhesive region is referred to as a bonding pad and has a rectangular structure.

FIG. 1 is a sectional view illustrating a structure of a bonding pad formed according to prior art methods. When a bonding pad forming process is performed, a pad opening portion 14a is generally formed within an insulating layer 14 by using a vertical etching process as shown in FIG. 1. Accordingly, a lower edge 14c of the pad opening portion 14a has an approximately right-angled profile. For this reason, while a subsequent process for forming a barrier metal layer 15 for preventing Cu from being diffused is performed, a pinch-off region 15a may occur in which the barrier metal layer 15 is not formed on the lower edge 14c of the pad opening portion 14a.

Subsequently, if Al is deposited to form an Al bonding pad 16 in the instance when a pinch-off region 15a is formed in the barrier metal layer 15, Cu of a Cu metal layer 12 positioned therebelow may be diffused through the pinch-off region 15a of the barrier metal layer 15 into the Al bonding pad 16 when a subsequent thermal process is performed.

Since Cu diffused into the Al bonding pad 16 causes particles to be generated, processing equipment may be polluted and the reliability of the device may decrease. Further, the bonding force between the Al bonding pad 16 and the Au wire (not shown) may be reduced when a subsequent packaging process is performed, thereby dropping yields.

### SUMMARY OF THE INVENTION

It is, therefore, an object of the present invention to provide a method for forming a bonding pad capable of preventing a pinch-off region from being generated in order not to diffuse Cu into the bonding pad by forming a sloped pad opening portion during a bonding pad forming process to unbrokenly form a barrier metal layer on a lower edge of the pad opening portion as well as the pad opening portion itself, and a semiconductor device having the bonding pad formed by the method.

In accordance with one aspect of the present invention, there is provided a method for forming a bonding pad comprising the steps of: (a) forming a first insulating film on a substrate or a lower metal wiring, and forming a first metal layer on the first insulating film; (b) forming a second insulating film on the first insulating film and the first metal layer, and a third insulating film on the second insulating film; (c) selectively slope-etching the third insulating film and the second insulating film using a first photosensitive film mask to form a sloped pad opening portion; (d) forming a barrier metal layer and a pad metal layer on the structure formed at step (c); (e) selectively etching the pad metal layer and the barrier metal layer by using a second photosensitive film mask to form a bonding pad; (f) forming a fourth insulating film on the structure formed at step (e); and (g) selectively etching the fourth insulating film by using a third photosensitive film mask to expose at least a part of the bonding pad.

In accordance with another aspect of the present invention, there is provided a method for forming a bonding pad comprising the steps of: (a) forming a first insulating film on a substrate or a lower metal wiring, and forming a first metal layer on the first insulating film; (b) forming a second insulating film on the first insulating film and the first metal layer, and a third insulating film on the second insulating film; (c) selectively vertical-etching the third insulating film by using a first photosensitive film mask to form a pad opening portion; (d) selectively slope-etching at least a part of the second insulating film exposed by the pad opening portion to allow a lower edge of the pad opening portion to be sloped; (e) forming a barrier metal layer and a pad metal layer on the structure formed at step (d); (f) selectively etching the pad metal layer and the barrier metal layer by using a second photosensitive film mask to form a bonding pad; (g) forming a fourth insulating film on the structure formed at step (f); and (h) selectively etching the fourth insulating film by using a third photosensitive film mask to expose at least a part of the bonding pad.

In accordance with still another aspect of the present invention, there is provided a method for forming a bonding pad comprising the steps of: (a) forming a first insulating film on a substrate or a lower metal wiring, and forming a first metal layer on the first insulating film; (b) forming a second insulating film on the first insulating film and the first metal layer, and a third insulating film on the second insulating film; (c) selectively etching the third insulating film by using a first photosensitive film mask to form a pad opening portion; (d) etching the second insulating film exposed by the pad opening portion and the third insulating film by using a chemical dry etching process to permit upper and lower edges of the pad opening portion to be sloped; (e) forming a barrier metal layer and a pad metal layer on the structure formed at step (d); (f) selectively etching the pad metal layer and the barrier metal layer by using a second photosensitive film mask to form a bonding pad; (g) forming a fourth insulating film on the structure formed at step (f); and (h) selectively etching the fourth insulating film by using a third photosensitive film mask to expose at least a part of the bonding pad.

In accordance with further still another aspect of the present invention, there is provided a method for forming a bonding pad comprising the steps of: (a) forming a first insulating film on a substrate or a lower metal wiring, and forming a first metal layer on the first insulating film; (b) forming a second insulating film on the first insulating film and the first metal layer, and a third insulating film on the second insulating film; (c) selectively etching the third insulating film by using a first photosensitive film mask to form a pad opening portion; (d) forming a spacer film on the structure formed at step (c), and etching the spacer film and the second insulating film to form a sloped spacer inside the pad opening portion; (e) forming a barrier metal layer and a pad metal layer film on the structure formed at step (d); (f) selectively etching the pad metal layer and the barrier metal layer by using a second photosensitive film mask to form a bonding pad; (g) forming a fourth insulating film on the structure formed at step (f); and (h) selectively etching the fourth insulating film by using a third photosensitive film mask to expose at least a part of the bonding pad.

In accordance with further still another aspect of the present invention, there is provided a semiconductor device comprising a bonding pad formed by using the method as described above.

### BRIEF DESCRIPTION OF THE DRAWINGS

The above and other objects and features of the present invention will become apparent from the following description of preferred embodiments given in conjunction with the accompanying drawings, in which:

FIG. 1 is a sectional view illustrating a bonding pad structure formed according to prior art methods;

FIGS. 2A to 2F are sectional views illustrating a method for forming a bonding pad in accordance with a first embodiment of the present invention;

FIGS. 3A to 3G are sectional views illustrating a method for forming a bonding pad in accordance with a second embodiment of the present invention;

FIGS. 4A to 4G are sectional views illustrating a method for forming a bonding pad in accordance with a third embodiment of the present invention; and

FIGS. 5A to 5G are sectional views illustrating a method for forming a bonding pad in accordance with a fourth embodiment of the present invention.

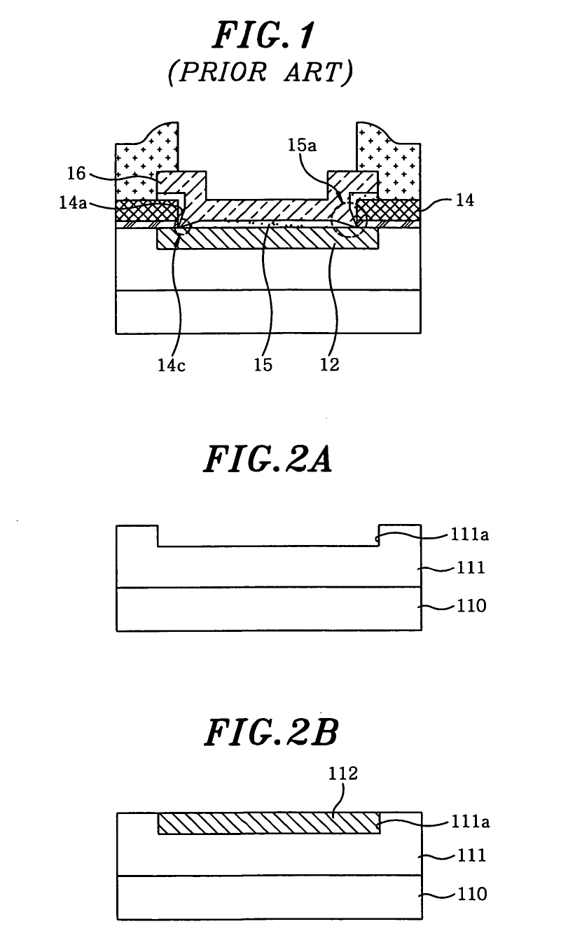

### DETAILED DESCRIPTION OF THE PREFERRED EMBODIMENTS

Reference now should be made to the drawings, in which the same reference numerals are used throughout the different drawings to designate the same or similar components.

Hereinafter, embodiments of the present invention will be described in detail with reference to the drawings.

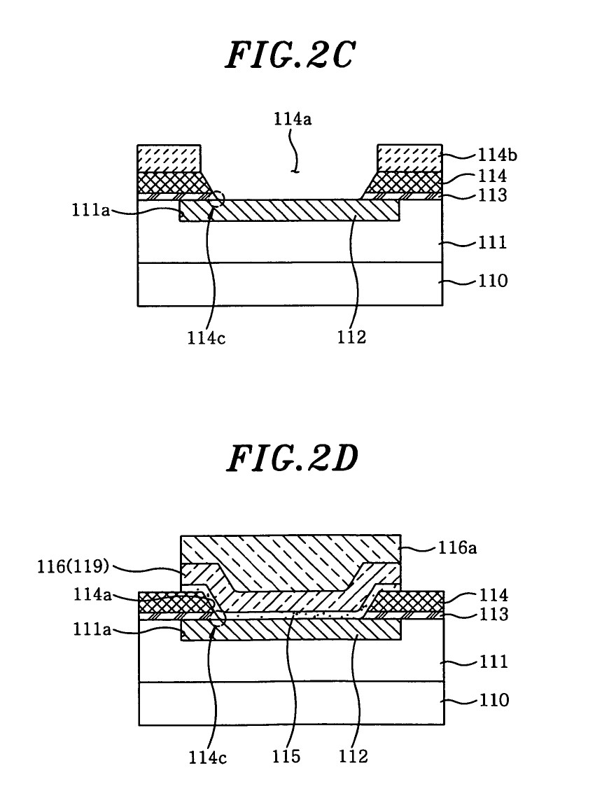

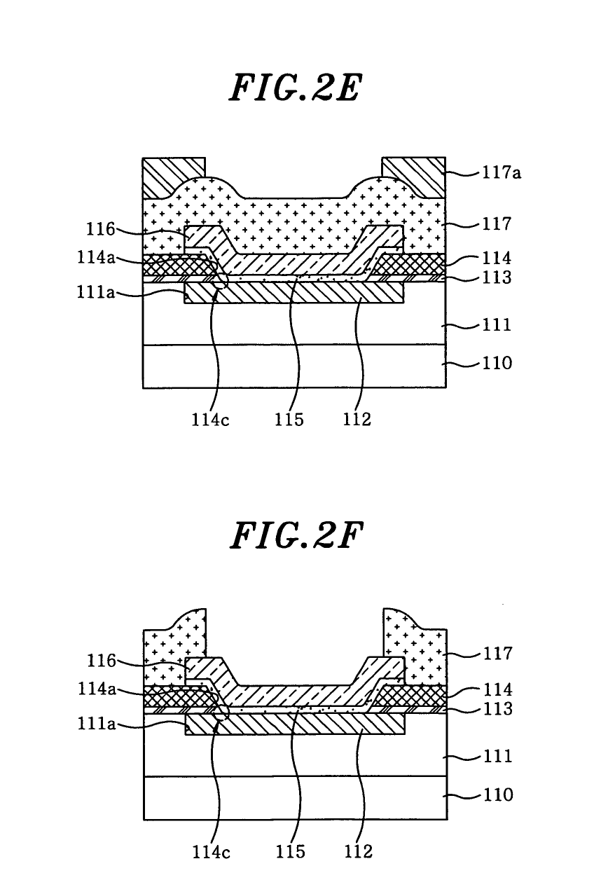

FIGS. 2A to 2F are cross-sectional views illustrating a method for forming a bonding pad in accordance with a first embodiment of the present invention.

Referring to FIG. 2A, a first insulating film 111 is formed as an interlayer insulating film on a substrate 110 or a lower metal wiring. Herein, the first insulating film 111 is made of, e.g., an undoped silicate glass (USG) film, a silicon oxide film (SiO₂), or a silicon nitride film (SiN₄). Subsequently, the first insulating film 111 is selectively etched by using a conventional photolithography process to form a void 111a in the first insulating film 111.

Then, as shown in FIG. 2B, a first metal layer 112 is formed on the first insulating film 111. Herein, the first metal layer 112 is made of Cu or a material including Cu. Subsequently, the first metal layer 112 is polished and planarized to expose the first insulating film 111. Preferably, the planarization is performed by using a chemical mechanical polishing process.

Then, as shown in FIG. 2C, a second insulating film 113 and a third insulating film 114 are sequentially formed over the substrate 110. Herein, the second insulating film 113 serves as a film for preventing Cu used in the first metal layer 112 from being diffused, and is made of a silicon nitride film or a silicon carbide (SiC) film. Further, the third insulating film 114 is preferably made of USG film, oxide film or silicon nitride film.

Subsequently, the third insulating film 114 and the second insulating film 113 are selectively slope-etched by using a first photosensitive film mask 114b to form a sloped pad opening portion 114a. Herein, etching conditions for slope-etching the third insulating film 114 and the second insulating film 113 are controlled so as to form the sloped pad opening portion 114a with an inclination angle of, preferably, about 5 to about 10 degrees. The pad opening portion 114a has a profile with an inclination angle of 5 to 10 degrees, so that a lower edge 114c thereof may not have a right-angled shape but a round shape.

Then, as shown in FIG. 2D, a barrier metal layer 115 and a pad metal layer 116 are formed over the substrate 110. Herein, the barrier metal layer 115 is preferably made of a tantalum (Ta) based thin film, a titanium (Ti) based thin film, or a Titanium Nitride based thin film, and the pad metal layer 116 is made of an aluminum (Al) based thin film. At this time, since the sloped pad opening portion 114a has a sloped surface with the inclination angle of 5 to 10 degrees, the barrier metal layer 115 is unbroken, uniformly formed even on the round-shaped lower edge 114c of the pad opening portion 114a so that a pinch-off region may not be generated. As a result, the phenomenon in which Cu of the first metal layer 112 is diffused into Al of the pad metal layer 116 may be prevented. Also, by preventing the diffusion phenomenon of Cu, it may be easy to control particle generation due to the diffusion phenomenon of Cu in a processing apparatus which may otherwise be possible.

Subsequently, the pad metal layer 116 and the barrier metal layer 115 are selectively etched by using a second photosensitive film mask 116a to form a bonding pad 119.

Then, as shown in FIG. 2E, a fourth insulating film 117 is formed over the substrate 110. Herein, the fourth insulating film 117 is preferably made of a USG film, oxide film, or silicon nitride film.

Subsequently, the fourth insulating film 117 is selectively etched by using a third photosensitive film mask 117a to expose at least a part of the bonding pad 116, thereby finishing the series processes for forming the bonding pad 116 as shown in FIG. 2F. At this time, the third photosensitive film mask 117a is preferably formed by the same photolithographic mask as that for the first photosensitive film mask 114b so that the number of photolithographic masks used in the processes may be reduced to thereby decrease a cost for the photolithographic process.

Subsequently, an Au wire (not shown) bonding process is performed to complete the semiconductor device. Herein, since the barrier metal layer 115 without the pinch-off phenomenon is formed by forming the sloped pad opening portion 114a, Cu of the first metal layer 112 may be prevented from being diffused into the Al of the bonding pad 116 so that the bonding force may be intensified while the Au wire bonding process is performed.

In accordance with the present invention, since the sloped pad opening portion is formed when the bonding pad forming process is performed, the barrier metal layer is unbroken and uniformly formed even on the lower edge of the pad opening portion so that the pinch-off phenomenon cannot occur.

Further, in accordance with the present invention, since the sloped pad opening portion allows the barrier metal layer to be formed without the pinch-off phenomenon, the diffusion phenomenon of Cu into Al of the bonding pad may be prevented, and the bonding force may also be intensified when the Au wire bonding process is performed.

Still further, in accordance with the present invention, since the sloped pad opening portion permits the diffusion phenomenon to be prevented, it is easy to control the particle generation due to the diffusion of Cu in the processing apparatus which may otherwise be possible.

Still further, in accordance with the present invention, since the third photosensitive film mask is formed by the same photolithographic mask as that for the first photosensitive film mask when the bonding pad forming process is performed, the number of photolithographic masks used in the processes may be reduced to thereby decrease a cost for the photolithographic process.

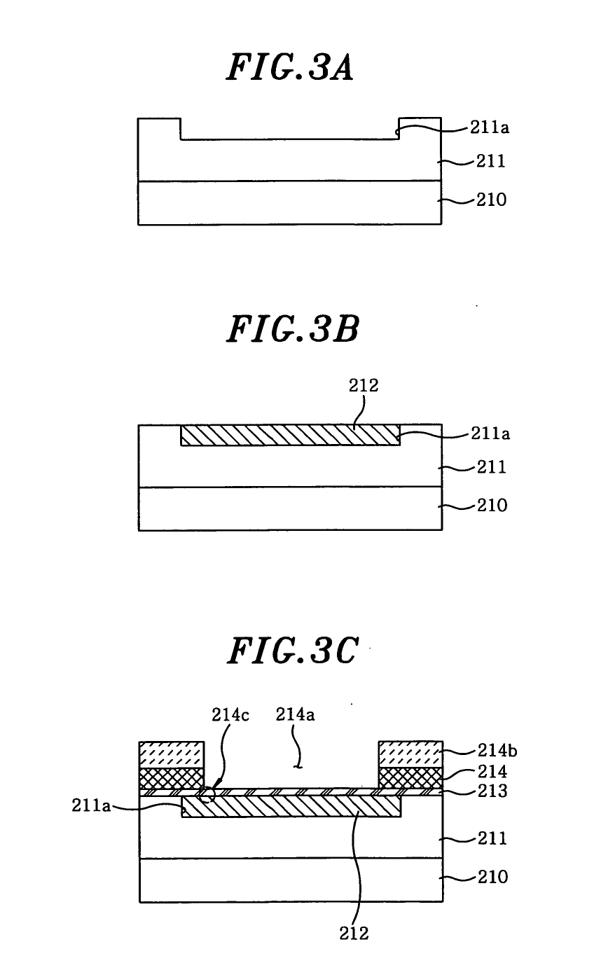

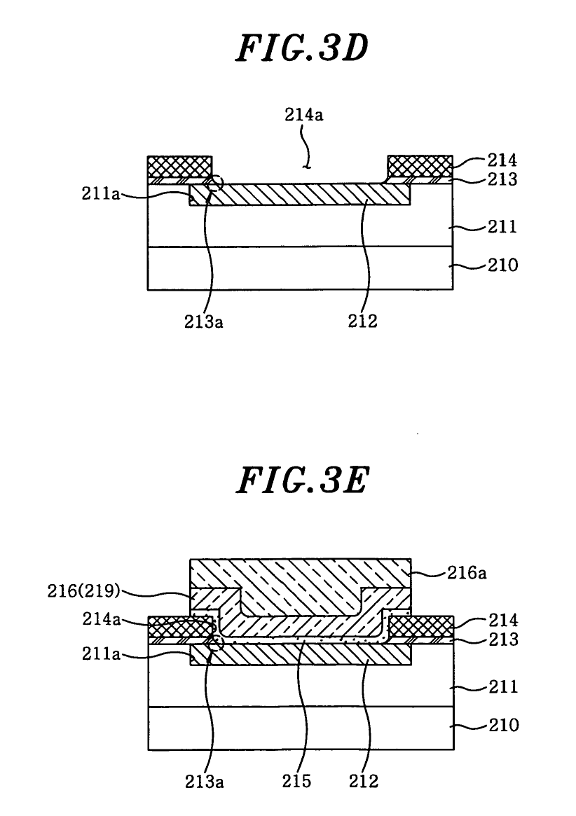

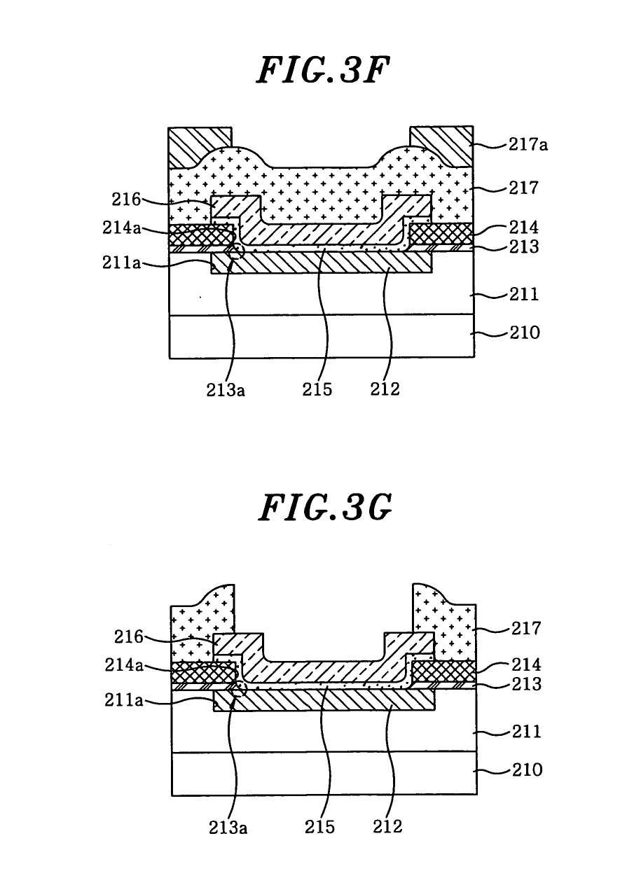

FIGS. 3A to 3G are cross-sectional views illustrating a method for forming a bonding pad in accordance with a second embodiment of the present invention.

A substrate 210, a first insulating film 211, a void 211a and a first metal layer 212 as shown in FIGS. 3A and 3B are identical to the substrate 110, the first insulating film 111, the void 111a and the first metal layer 112 of the first embodiment and therefore will not be described in detail for the sake of simplicity.

As shown in FIG. 3C, a second insulating film 213 and a third insulating film 214 are sequentially formed over the substrate 210. Herein, the second insulating film 213 serves as a film for preventing Cu used in the first metal layer 212 from being diffused, and is made of a silicon nitride film or a silicon carbide (SiC) film. Further, the third insulating film 214 is preferably made of USG film, oxide film or silicon nitride film. Subsequently, the third insulating film 214 is selectively vertical-etched by using the first photosensitive film mask 214b to form a pad opening portion 214a. Herein, since the third insulating film 214 is vertical-etched, a lower edge 214c of the pad opening portion 214a has a profile similar to a right-angled shape.

Then, as shown in FIG. 3D, the second insulating film 213 exposed on the pad opening portion is slope-etched, allowing a lower edge 213a of the pad opening portion 214a to be sloped. Herein, etching conditions for slope-etching the second insulating film 213 are controlled so as to form the second insulating film 213 with an inclination angle of, preferably, about 5 to about 10 degrees. At this time, the lower edge 213a of the pad opening portion 214a is sloped with a slope of 5 to 10 degrees, and it does not have a right-angled shape but a round shape.

Then, as shown in FIG. 3E, a barrier metal layer 215 and a pad metal layer 216 are formed over the substrate 210. Herein, the barrier metal layer 215 is preferably made of a Ta based thin film, a Ti based thin film, or a Titanium Nitride based thin film, etc., and the pad metal layer 216 is made of an aluminum based thin film. At this time, since the lower edge 213a of the pad opening portion 214a has a sloped surface with an inclination angle of about 5 to about 10 degrees, the barrier metal layer 215 is unbroken and uniformly formed in the pad opening portion 214a so that the pinch-off region may not be generated. As a result, the phenomenon in which Cu of the first metal layer 212 is diffused into Al of the pad metal layer 216 may be prevented. Also, by preventing the diffusion phenomenon, it is easier to control particle generation due to the diffusion phenomenon of Cu in a processing apparatus which may otherwise be possible.

Subsequently, the pad metal layer 216 and the barrier metal layer 215 are selectively etched by using a second photosensitive film mask 216a to form a bonding pad 219.

Then, as shown in FIG. 3F, a fourth insulating film 217 is formed over the substrate 210. Herein, the fourth insulating film 217 is preferably made of USG film, oxide film, or silicon nitride film.

Subsequently, the fourth insulating film 217 is selectively etched by using a third photosensitive film mask 217a to expose at least a part of the bonding pad 216, thereby finishing the series of processes for forming the bonding pad 216 as shown in FIG. 3G. The third photosensitive film mask 217a is preferably formed by the same photolithographic mask as that for the first photosensitive film mask 214b so that the number of photolithographic masks used in the processes may be reduced to thereby decrease the cost of the photolithographic process.

Subsequently, an Au wire (not shown) bonding process is performed to accomplish a semiconductor device. Herein, since the barrier metal layer 215 without the pinch-off phenomenon is formed by sloping the lower edge 213a of the pad opening portion 214a, Cu of the first metal layer 212 may be prevented from being diffused into the Al of the bonding pad 216 so that the bonding force may be intensified while the Au wire bonding process is performed.

In accordance with the present invention, since the lower edge of the pad opening portion is sloped when the bonding pad forming process is performed, the barrier metal layer is unbroken and uniformly formed in the pad opening portion so that the pinch-off phenomenon cannot be generated.

Further, in accordance with the present invention, since the sloped lower edge of the pad opening portion allows the barrier metal layer to be formed without the pinch-off phenomenon, the diffusion phenomenon of Cu into Al of the bonding pad may be prevented, and the bonding force may also be intensified when the Au wire bonding process is performed.

Still further, in accordance with the present invention, since the sloped lower edge of the pad opening portion permits the diffusion phenomenon of Cu to be prevented, it is easy to control the particle generation due to the diffusion of Cu in the processing apparatus which may otherwise be possible.

Still further, in accordance with the present invention, since the third photosensitive film mask is formed by the same photolithographic mask as that for the first photosensitive film mask, the number of photolithographic masks used in the process may be reduced to thereby decrease the cost of the photolithographic process.

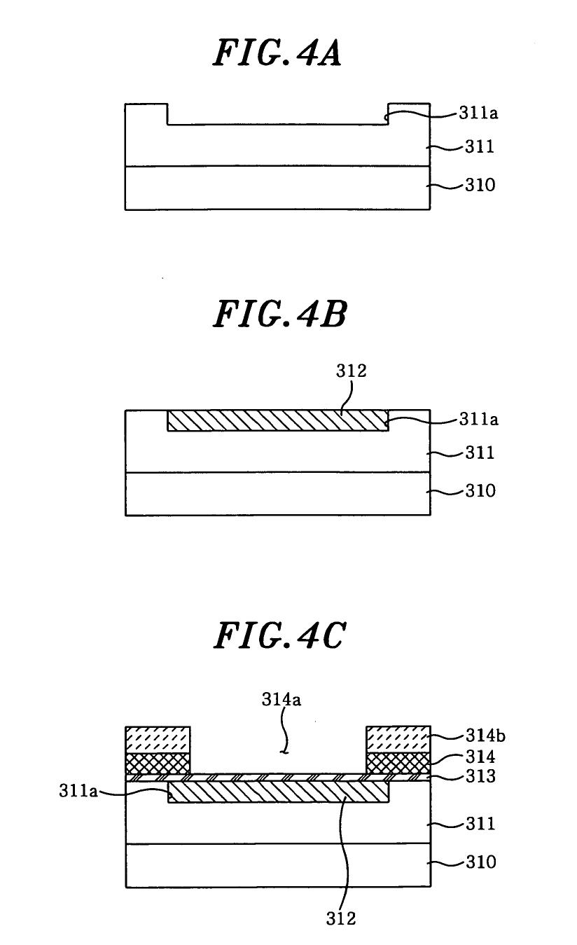

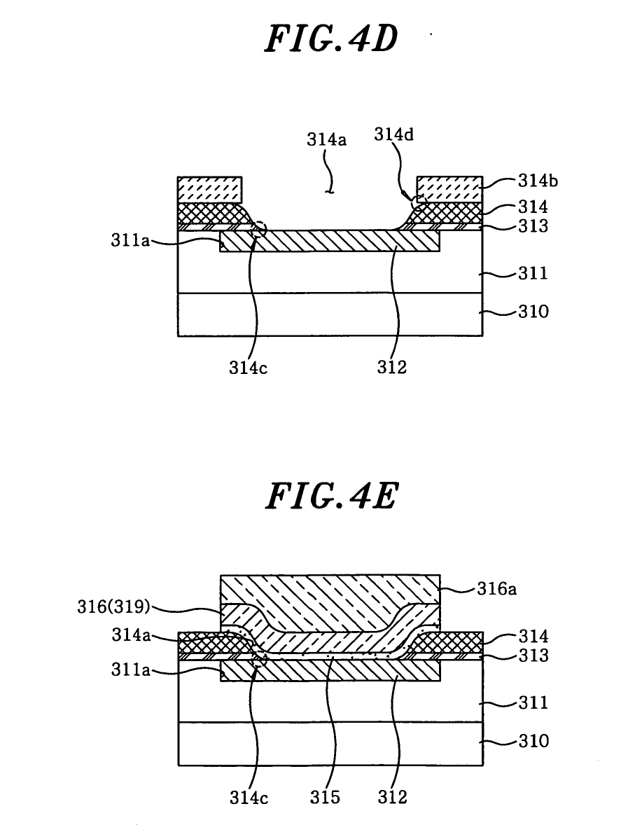

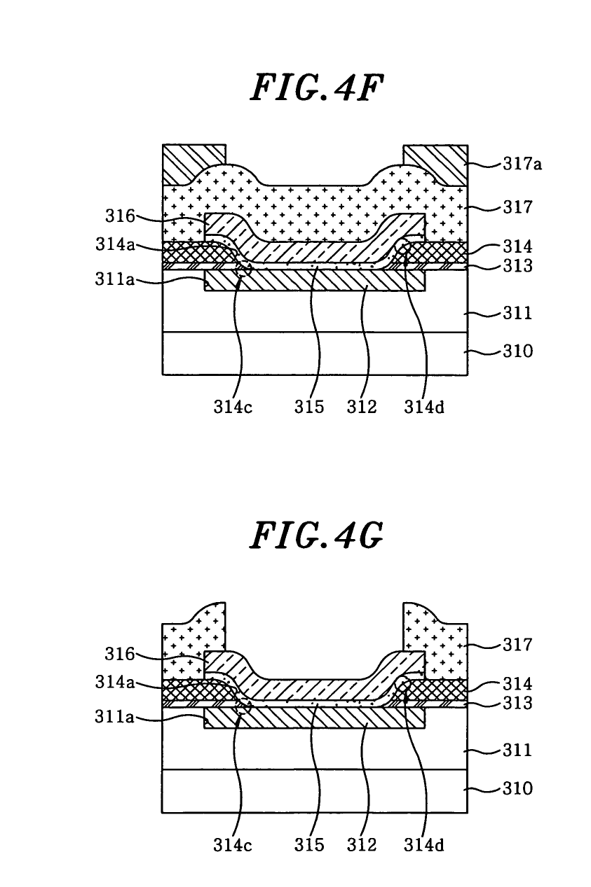

FIGS. 4A to 4G are cross-sectional views illustrating a method for forming a bonding pad in accordance with a third embodiment of the present invention.

A substrate 310, a first insulating film 311, a void 311a and a first metal layer 312 as shown in FIGS. 4A and 4B are identical to the substrate 110, the first insulating film 111, the void 111a and the first metal layer 112 of the first embodiment and therefore will not be described in detail for the sake of simplicity.

As shown in FIG. 4C, a second insulating film 313 and a third insulating film 314 are sequentially formed over the substrate 310. Herein, the second insulating film 313 serves as a film for preventing Cu used as the first metal layer 312 from being diffused, and is made of a silicon nitride film or a silicon carbide (SiC) film. Further, the third insulating film 314 is preferably made of a USG film, oxide film or silicon nitride film. Subsequently, the third insulating film 314 is selectively vertical-etched by using the first photosensitive film mask 314b to form a pad opening portion 314a. Herein, since the third insulating film 314 is vertical-etched, the pad opening portion 314a has an approximately right-angled profile.

Then, as shown in FIG. 4D, the second insulating film 313 exposed on the pad opening portion is etched by a chemical dry etching (CDE) process. Herein, the CDE process is performed so that the second insulating film 313 is isotropically etched by using a chemical mixed gas such as CF₄ and O₂. When the second insulating film 313 is etched by the CDE process, the third insulating film 314 is also isotropically etched by a chemical mixed gas process, so that upper and lower edges 314d and 314c of the pad opening portion 314a may be sloped to have a round shape.

Then, as shown in FIG. 4E, a barrier metal layer 315 and a pad metal layer 316 are formed over the substrate 310. Herein, the barrier metal layer 315 is preferably made of a Ta based thin film, Ti based thin film, or Titanium Nitride based thin film, and the pad metal layer 316 is made of an aluminum based thin film. At this time, since the upper edge 314d and the lower edge 313c have a sloped surface, the barrier metal layer 315 is unbroken and uniformly formed in the pad opening portion 314a so that the pinch-off region may not be generated. As a result, the phenomenon in which Cu of the first metal layer 312 is diffused into Al of the pad metal layer 316 may be prevented. Also, by preventing the diffusion phenomenon of Cu, it is easier to control particle generation due to the diffusion phenomenon of Cu in a processing apparatus which may otherwise be possible.

Subsequently, the pad metal layer 316 and the barrier metal layer 315 are selectively etched by using a second photosensitive film mask 316a to form a bonding pad 319.

Then, as shown in FIG. 4F, a fourth insulating film 317 is formed over the substrate 310. Herein, the fourth insulating film 317 is preferably made of USG film, oxide film, or silicon nitride film.

Subsequently, the fourth insulating film 317 is selectively etched by using a third photosensitive film mask 317a to expose a part of the bonding pad 316, thereby completing the series of processes for forming the bonding pad 316 as shown in FIG. 4G. The third photosensitive film mask 317a is preferably formed by the same photolithographic mask as the first photosensitive film mask 314b so that the number of photolithographic masks used in the processes may be reduced to thereby decrease the cost of the photolithographic process.

Subsequently, an Au wire (not shown) bonding process is performed to complete the semiconductor device. Herein, since the barrier metal layer 315 without the pinch-off phenomenon is formed by sloping the lower edge 313a of the pad opening portion 314a, Cu of the first metal layer 312 may be prevented from being diffused into Al of the bonding pad 316 so that the bonding force may be intensified while the Au wire bonding process is performed.

In accordance with the present invention, since the upper and the lower edges of the pad opening portion are sloped when the bonding pad process is performed, the barrier metal layer is unbroken and uniformly formed in the pad opening portion so that the pinch-off phenomenon cannot be generated.

Further, in accordance with the present invention, since the sloped upper and lower edges of the pad opening portion allow the barrier metal layer to be formed without the pinch-off phenomenon, the diffusion phenomenon of Cu into Al of the bonding pad may be prevented, and the bonding force may also be intensified when the Au wire bonding process is performed.

Still further, in accordance with the present invention, since the sloped upper and lower edges of the pad opening portion permit the diffusion phenomenon of Cu to be prevented, it is easier to control the particle generation due to the diffusion of Cu in the processing apparatus which may otherwise be possible.

Still further, in accordance with the present invention, since the third photosensitive film mask is formed by the same photolithographic mask as the first photosensitive film mask when the bonding pad process is performed, the number of photolithographic masks used in the processes may be reduced to thereby decrease the cost of the photolithographic process.

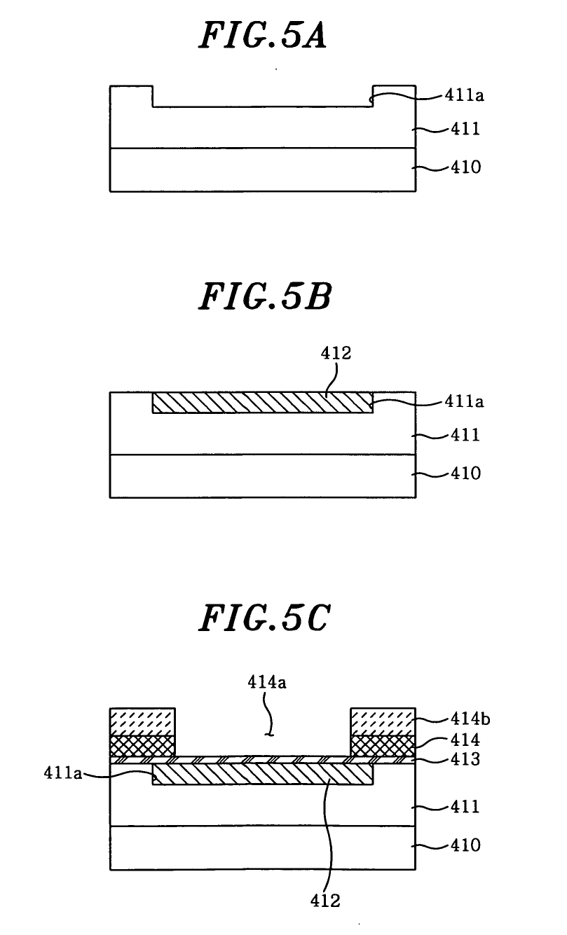

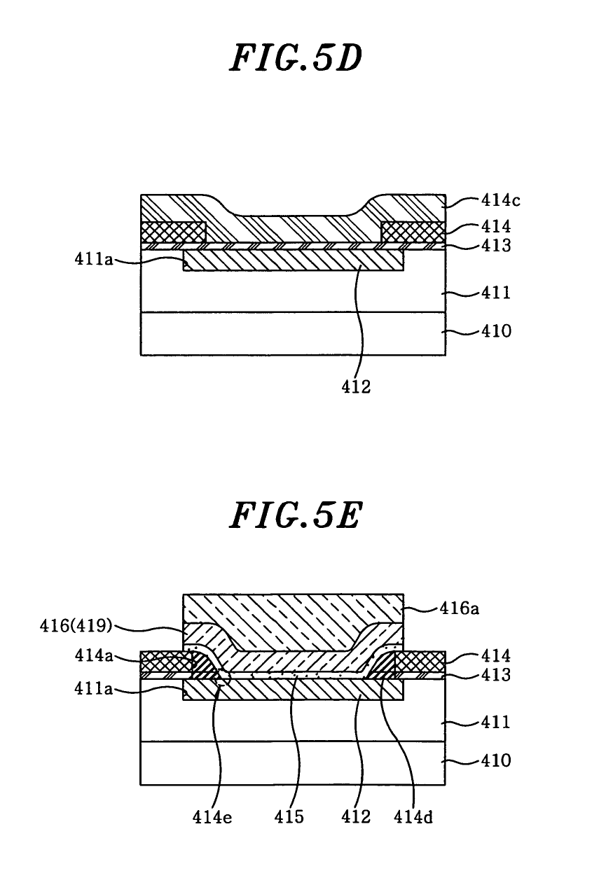

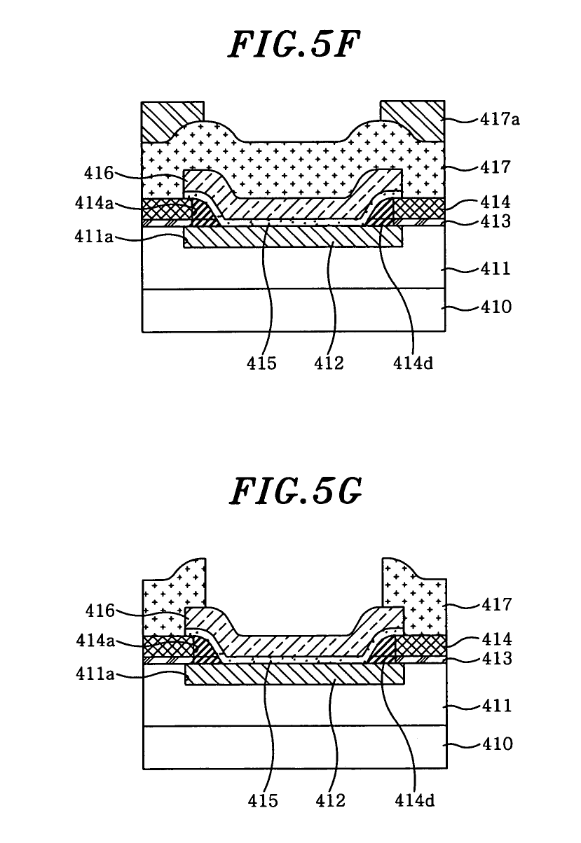

FIGS. 5A to 5G are cross-sectional views illustrating a method for forming a bonding pad in accordance with a fourth and final embodiment of the present invention.

A substrate 410, first insulating film 411, void 411a and first metal layer 412 as shown in FIGS. 5A and 5B are identical to the substrate 110, the first insulating film 111, the void 111a and the first metal layer 112 of the first embodiment and therefore will not be described in detail for the sake of simplicity.

As shown in FIG. 5C, a second insulating film 413 and a third insulating film 414 are sequentially formed over the substrate 410. Herein, the second insulating film 413 serves as a film for preventing Cu used in the first metal layer 412 from being diffused, and is made of a silicon nitride film or a silicon carbide (SiC) film. Further, the third insulating film 414 is preferably made of a USG film, oxide film or silicon nitride film. Subsequently, the third insulating film 414 is selectively vertical-etched by using the first photosensitive film mask 414b to form a pad opening portion 414a.

Then, as shown in FIG. 5D, a spacer film 414c is formed over the substrate 410. The spacer film 414c is preferably made of a silicon nitride film or a silicon carbide film. At this time, the spacer film 414c is made of the same material as that of the second insulating film 413 so that it may be used as a film for preventing Cu from being diffused like the second insulating film 413.

Next, as shown in FIG. 5E, the spacer film 414c and the second insulating film 413 are wholly etched to form a sloped spacer 414d inside the pad opening portion 414a. Herein, the etching is performed so that the substrate may be wholly etched without a photosensitive film mask to form the sloped spacer 414d inside the pad opening portion 414a, wherein the sloped spacer 414d is composed of the spacer film 414c and the second insulating film 413.

Subsequently, as shown in FIG. 5E, a barrier metal layer 415 and a pad metal layer 416 are formed over the substrate 410. Herein, the barrier metal layer 415 is preferably made of a Ta based thin film, Ti based thin film, or Titanium Nitride based thin film, and the pad metal layer 416 is made of an aluminum based thin film. At this time, since the sloped spacer 414d is formed inside the pad opening portion, the barrier metal layer 415 is unbroken and uniformly formed along the sloped spacer 414d and inside the pad opening portion 414a so that a pinch-off region may not be formed at a lower edge 414e of the pad opening portion 414a. As a result, the phenomenon in which Cu of the first metal layer 412 is diffused into Al of the pad metal layer 416 may be prevented. Also, by preventing the diffusion phenomenon of Cu, it is easier to control particle generation due to the diffusion phenomenon of Cu in a processing apparatus which may otherwise be possible.

Subsequently, the pad metal layer 416 and the barrier metal layer 415 are selectively etched by using a second photosensitive film mask 416a to form a bonding pad 419.

Then, as shown in FIG. 5F, a fourth insulating film 417 is formed over the substrate 410. Herein, the fourth insulating film 417 is preferably made of a USG film, oxide film, or silicon nitride film.

Subsequently, the fourth insulating film 417 is selectively etched by using a third photosensitive film mask 417a to expose at least a part of the bonding pad 416, thereby completing the series of processes for forming the bonding pad 416 as shown in FIG. 5G. The third photosensitive film mask 417a is preferably formed by the same photolithographic mask as the first photosensitive film mask 414b so that the number of photolithographic masks used in the processes may be reduced to thereby decrease the cost of the photolithographic process.

Subsequently, an Au wire (not shown) bonding process is performed to complete the semiconductor device. Herein, since the barrier metal layer 415 without the pinch-off phenomenon is formed by sloping the lower edge 413a of the pad opening portion 414a, Cu of the first metal layer 412 may be prevented from being diffused into Al of the bonding pad 416 so that the bonding force may be intensified while the Au wire bonding process is performed.

In accordance with the present invention, since the sloped spacer is formed inside the pad opening portion when the bonding pad forming process is performed, the barrier metal layer is unbroken and uniformly formed along the sloped spacer of the pad opening portion so that the pinch-off phenomenon cannot be generated.

Further, in accordance with the present invention, since the sloped spacer of the pad opening portion allows the barrier metal layer to be formed without the pinch-off phenomenon, the diffusion phenomenon of Cu of the first metal layer into Al of the bonding pad may be prevented, and the bonding force may also be intensified when the Au wire bonding process is performed.

Still further, in accordance with the present invention, since the sloped spacer of the pad opening portion permits the diffusion phenomenon of Cu to be prevented, it is easy to control the particle generation due to the diffusion of Cu in the processing apparatus which may otherwise be possible.

Still further, in accordance with the present invention, since the third photosensitive film mask is formed by the same photolithographic mask as that for the first photosensitive film mask when the bonding pad process is performed, the number of photolithographic masks used in the processes may be reduced to thereby decrease the cost of the photolithographic process.

The preferred embodiments of the present invention have been disclosed for illustrative purposes. Although specific terms have been used, these terms are merely used with general meanings to allow technical constitutions of the present invention to be easily described and to allow the present invention to be easily understood, but are not used to limit the scope of the present invention. Those skilled in the art will appreciate that various modifications, additions and substitutions are possible, without departing from the scope and spirit of the invention as disclosed in the accompanying claims.

What is claimed is:

1. A method for forming a bonding pad comprising the steps of:
(a) forming a first insulating film on a substrate or a lower metal wiring, and forming a first metal layer on the first insulating film;
(b) forming a second insulating film on the first insulating film and the first metal layer, and a third insulating film on the second insulating film;
(c) selectively slope-etching the third insulating film and the second insulating film using a first photosensitive film mask to form a sloped pad opening portion;
(d) forming a barrier metal layer and a pad metal layer on the structure formed at step (c);
(e) selectively etching the pad metal layer and the barrier metal layer by using a second photosensitive film mask to form a bonding pad;
(f) forming a fourth insulating film on the structure formed at step (e); and
(g) selectively etching the fourth insulating film by using a third photosensitive film mask to expose at least a part of the bonding pad.

2. The method as claimed in claim 1, wherein, at step (a), the first metal layer is made of Cu or a material including Cu.

3. The method as claimed in claim 2, wherein, at step (b), the second insulating film serves as a film for preventing Cu from diffusing into the bonding pad, and is made of at least one of a silicon nitride film and a silicon carbide film.

4. The method as claimed in claim 1, wherein, at step (c), the second and third insulating films are slope-etched to form the pad opening portion with an inclination angle of about 5 to about 10 degrees.

5. The method as claimed in claim 1, wherein, at step (d), the barrier metal layer is made of a material selected from the group consisting of Ta based material, Ti based material and Titanium Nitride based material.

6. The method as claimed in claim 1, wherein, at step (d), the pad metal layer is made of an Al based material.

7. The method as claimed in claim 1, wherein, at step (g), the third photosensitive film mask is formed using the same photolithographic mask as that used for the first photosensitive film mask.

8. A method for forming a bonding pad comprising the steps of:
(a) forming a first insulating film on a substrate or a lower metal wiring, and forming a first metal layer on the first insulating film;
(b) forming a second insulating film on the first insulating film and the first metal layer, and a third insulating film on the second insulating film;
(c) selectively vertical-etching the third insulating film by using a first photosensitive film mask to form a pad opening portion;
(d) selectively slope-etching at least a part of the second insulating film exposed by the pad opening portion to allow a lower edge of the pad opening portion to be sloped;
(e) forming a barrier metal layer and a pad metal layer on the structure formed at step (d);
(f) selectively etching the pad metal layer and the barrier metal layer by using a second photosensitive film mask to form a bonding pad;
(g) forming a fourth insulating film on the structure formed at step (f); and
(h) selectively etching the fourth insulating film by using a third photosensitive film mask to expose at least a part of the bonding pad.

9. The method as claimed in claim 8, wherein, at step (a), the first metal layer is made of Cu or a material including Cu.

10. The method as claimed in claim 9, wherein, at step (b), the second insulating film serves as a film for preventing Cu from diffusing into the bonding pad, and is made of at least one of a silicon nitride film and a silicon carbide film.

11. The method as claimed in claim 8, wherein, at step (d), the second insulating film is slope-etched to have an inclination angle of about 5 to about 10 degrees.

12. The method as claimed in claim 8, wherein, at step (e), the barrier metal layer is made of a material selected from the group consisting of Ta based material, Ti based material and Titanium Nitride based material.

13. The method as claimed in claim 8, wherein, at step (e), the pad metal layer is made of an Al based material.

14. The method as claimed in claim 8, wherein, at step (h), the third photosensitive film mask is formed using the same photolithographic mask as that used for the first photosensitive film mask.

15. A method for forming a bonding pad comprising the steps of:
(a) forming a first insulating film on a substrate or a lower metal wiring, and forming a first metal layer on the first insulating film;
(b) forming a second insulating film on the first insulating film and the first metal layer, and a third insulating film on the second insulating film;
(c) selectively etching the third insulating film by using a first photosensitive film mask to form a pad opening portion;
(d) etching the second insulating film exposed by the pad opening portion and the third insulating film by using a chemical dry etching process to permit upper and lower edges of the pad opening portion to be sloped;
(e) forming a barrier metal layer and a pad metal layer on the structure formed at step (d);
(f) selectively etching the pad metal layer and the barrier metal layer by using a second photosensitive film mask to form a bonding pad;
(g) forming a fourth insulating film on the structure formed at step (f); and
(h) selectively etching the fourth insulating film by using a third photosensitive film mask to expose at least a part of the bonding pad.

16. The method as claimed in claim 15, wherein, at step (a), the first metal layer is made of Cu or a material including Cu.

17. The method as claimed in claim 16, wherein, at step (b), the second insulating film serves as a film for preventing Cu from diffusing into the bonding pad, and is made of at least one of a silicon nitride film and a silicon carbide film.

18. The method as claimed in claim 15, wherein, at step (d), the chemical dry etching process is performed so that the second and the third insulating films are isotropically etched by using a chemical mixed gas.

19. The method as claimed in claim 18, wherein the chemical mixed gas is CF₄ and O₂.

20. The method as claimed in claim 15, wherein, at step (e), the barrier metal layer is made of a material selected from the group consisting of Ta based material, Ti based material and Titanium Nitride based material.

21. The method as claimed in claim 15, wherein, at step (e), the pad metal layer is made of an Al based material.

22. The method as claimed in claim 15, wherein, at step (h), the third photosensitive film mask is formed using the same photolithographic mask as that used for the first photosensitive film mask.

23. A method for forming a bonding pad comprising the steps of:
(a) forming a first insulating film on a substrate or a lower metal wiring, and forming a first metal layer on the first insulating film;
(b) forming a second insulating film on the first insulating film and the first metal layer, and a third insulating film on the second insulating film;
(c) selectively etching the third insulating film by using a first photosensitive film mask to form a pad opening portion;
(d) forming a spacer film on the structure formed at step
(c), and etching the spacer film and the second insulating film to form a sloped spacer inside the pad opening portion;
(e) forming a barrier metal layer and a pad metal layer film on the structure formed at step (d);
(f) selectively etching the pad metal layer and the barrier metal layer by using a second photosensitive film mask to form a bonding pad;
(g) forming a fourth insulating film on the structure formed at step (f); and
(h) selectively etching the fourth insulating film by using a third photosensitive film mask to expose at least a part of the bonding pad.

24. The method as claimed in claim 23, wherein, at step (a), the first metal layer is made of Cu or a material including Cu.

25. The method as claimed in claim 24, wherein, at step (b), the second insulating film serves as a film for preventing Cu from diffusing into the bonding pad, and is made of at least one of a silicon nitride film and a silicon carbide film.

26. The method as claimed in claim 23, wherein, at step (d), the spacer film is made of the same material as the second insulating film.

27. The method as claimed in claim 23, wherein, at step (d), the spacer film is made of a silicon nitride film or a silicon carbide film.

28. The method as claimed in claim 23, wherein, at step (e), the barrier metal layer is made of a material selected from the group consisting of Ta based material, Ti based material and Titanium Nitride based material.

29. The method as claimed in claim 23, wherein, at step (e), the pad metal layer is formed of an Al based material.

30. The method as claimed in claim 23, wherein, at step (h), the third photosensitive film mask is formed using the same photolithographic mask as that used for the first photosensitive film mask.

31. A semiconductor device comprising a bonding pad formed by using the method as claimed in claim 1.

32. A semiconductor device comprising a bonding pad formed by using the method as claimed in claim 8.

33. A semiconductor device comprising a bonding pad formed by using the method as claimed in claim 15.

34. A semiconductor device comprising a bonding pad formed by using the method as claimed in claim 23.
